(19) United States
(12) Patent Application Publication
(10) Pub. No.: US 2026/0258242 A1
(43) Pub. Date: Sep. 3, 2026

(54) RESIN COMPOSITION FOR ANTI-REFLECTIVE FILM, ANTI-REFLECTIVE FILM AND SOLID STATE IMAGING DEVICE

(71) Applicant: DONGWOO FINE-CHEM CO., LTD., Iksan-si (KR)

(72) Inventors: Jung Ok YUN, Iksan-si (KR); Yongho OH, Iksan-si (KR); Jeongsik KIM, Iksan-si (KR); Boeun AHN, Iksan-si (KR); Hojun YOON, Iksan-si (KR)

(73) Assignee: DONGWOO FINE-CHEM CO., LTD., Iksan-si (KR)

(21) Appl. No.: 19/536,478

(22) Filed: Feb. 11, 2026

(30) Foreign Application Priority Data
Feb. 28, 2025 (KR) 10-2025-0026907
Dec. 8, 2025 (KR) 10-2025-0192710

(51) Int. Cl. C08L 63/00

(52) U.S. Cl. CPC C08L 63/00

(57) ABSTRACT

The present invention provides a resin composition for an anti-reflective film comprising hollow aluminosilicate particles, a binder resin, and a solvent, in which the hollow aluminosilicate particles have a Si/Al molar ratio of 7 to 15, surfaces of which are modified with a silane compound having a specific structure or a non-reactive resin, and the binder resin contains a polysiloxane compound, an anti-reflective film formed therefrom, and a solid-state imaging device having the anti-reflective film. The resin composition for an anti-reflective film according to the present invention exhibits a low refractive index, suppresses crack during film formation, provides excellent film flatness, prevents particle aggregation and foreign matter generation, inhibits moisture adsorption under high temperature and humidity conditions, and blocks moisture permeation by developers and strippers.

### CROSS REFERENCE TO RELATED APPLICATIONS

The instant application claims priority based on Korean Patent Application No. 10-2025-0026907, filed Feb. 28, 2025 and Korean Patent Application No. 10-2025-0192710, filed Dec. 8, 2025, the entire contents of which are incorporated herein by reference.

### TECHNICAL FIELD

The present invention relates to a resin composition for an anti-reflective film, an anti-reflective film, and a solid-state imaging device, more specifically to a resin composition for an anti-reflective film, an anti-reflective film, and a solid-state imaging device, exhibiting low refractive index, suppressing crack during film formation, providing excellent film flatness, preventing particle aggregation and foreign matter generation, inhibiting moisture adsorption under high temperature and humidity conditions, and blocking moisture permeation by developers and strippers.

### BACKGROUND ART

A solid-state imaging device is a device that converts images captured through light energy into electrical information, in which a micro lens for focusing light is formed on a photoelectric conversion device and an anti-reflective film is formed on its surface. This anti-reflective film prevents noise such as flare and ghosting.

The anti-reflective film applied to solid-state imaging devices requires fine and precise processing and molding capabilities. Consequently, vapor deposition methods suitable for fine processing, such as vacuum deposition or sputtering, have been employed.

However, these vapor deposition methods, including vacuum deposition and sputtering, suffer from high manufacturing costs due to the high price of equipment and other factors.

Therefore, coating methods have been proposed in which a composition capable of forming an anti-reflective film is applied to a substrate and cured as an alternative to vapor deposition.

For example, Korean Patent Publication No. 10-2010-0123610 discloses a method for forming an anti-reflective film by applying a coating solution containing hollow silica particles as low-refractive-index particles and a binder resin.

However, conventional compositions for anti-reflective films using hollow silica particles had problems such as cracking during film formation, poor film flatness, moisture adsorption under high temperature and humidity conditions, and moisture permeation by developers and strippers.

Furthermore, untreated hollow silica particles exhibit hydrophilic surface characteristics, causing them to absorb moisture from the air. This leads to particle aggregation and reduced flowability. Additionally, the particles have poor miscibility with the polymeric materials or organic solvents in the composition, potentially causing foreign matter contamination and resulting in quality degradation issues.

Therefore, there is a demand for the development of a resin composition for anti-reflective films that exhibits a low refractive index, suppresses crack during film formation, provides excellent film flatness, prevents particle aggregation and foreign matter generation, inhibits moisture adsorption under high temperature and humidity conditions, and blocks moisture permeation by developers and strippers.

### DISCLOSURE

### Technical Problem

An object of the present invention is to provide a resin composition for an anti-reflective film that exhibits a low refractive index, suppresses crack during film formation, provides excellent film flatness, prevents particle aggregation and foreign matter generation, inhibits moisture adsorption under high temperature and humidity conditions, and blocks moisture permeation by developers and strippers.

Another object of the present invention is to provide an anti-reflective film formed using the above-mentioned resin composition for an anti-reflective film.

Yet another object of the present invention is to provide a solid-state imaging device having the above-mentioned anti-reflective film.

### Technical Solution

According to an aspect, the present invention provides a resin composition for an anti-reflective film comprising hollow aluminosilicate particles, a binder resin, and a solvent, wherein the hollow aluminosilicate particles have a Si/Al molar ratio of 7 to 15, surfaces of which are modified with a compound of the following formula (1) or a non-reactive resin, and the binder resin comprises a polysiloxane compound:

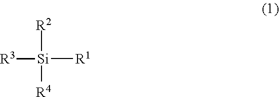

wherein,
R¹ is C₁-C₂₀ alkyl,
R² to R⁴ are each independently C₁-C₄ alkoxy.

In one embodiment of the present invention, the average particle diameter of the hollow aluminosilicate particles may be 30 to 150 nm.

In one embodiment of the present invention, the non-reactive resin may comprise a repeating unit of the following formula (2):

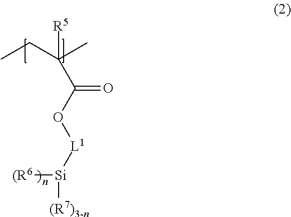

wherein,
R⁵ is hydrogen or methyl,
L¹ is absent, or C₁-C₁₀ alkylene or C₁-C₁₀ oxyalkylene,
R⁶ is hydroxy, C₁-C₄ alkoxy, or halogen,
R⁷ is hydrogen or C₁-C₂₀ alkyl, and
n is an integer from 1 to 3.

In one embodiment of the present invention, the polysiloxane compound may comprise a hydrolysis condensation product of a silane compound of the following formula (4):

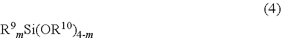

wherein,
R⁹ is C₁-C₂₀ alkyl, vinyl, aryl, or aralkyl.
R¹⁰ is C₁-C₄ alkyl, and
m is an integer from 0 to 3.

The resin composition for an anti-reflective film according to one embodiment of the present invention may further comprise amorphous silica particles.

The resin composition for an anti-reflective film according to one embodiment of the present invention may satisfy the following Equation 1:

$$1 \leq a / b \leq 15 \qquad [ Equation 1 ]$$

wherein,
a is an average particle diameter of the hollow aluminosilicate particles, and
b is an average particle diameter of the amorphous silica particles.

In one embodiment of the present invention, a cured film formed from the resin composition for an anti-reflective film may have a refractive index of 1.10 to 1.35 at 550 nm.

According to another aspect, the present invention provides an anti-reflective film formed using the above-mentioned resin composition for an anti-reflective film.

According to yet another aspect, the present invention provides a solid-state imaging device having the above-mentioned anti-reflective film.

### Advantageous Effects

The resin composition for an anti-reflective film according to the present invention exhibits a low refractive index, suppresses crack during film formation, provides excellent film flatness, prevents particle aggregation and foreign matter generation, inhibits moisture adsorption under high temperature and humidity conditions, and blocks moisture permeation by developers and strippers. Therefore, the resin composition for an anti-reflective film according to the present invention can be advantageously applied to anti-reflective films of solid-state imaging devices.

### BEST MODE

Hereinafter, the present invention will be described in more detail.

One embodiment of the present invention relates to a resin composition for an anti-reflective film comprising hollow aluminosilicate particles (A), a binder resin (C), and a solvent (D),
wherein the hollow aluminosilicate particles have a Si/Al molar ratio of 7 to 15, surfaces of which are modified with a compound of the following formula (1) or a non-reactive resin, and
the binder resin comprises a polysiloxane compound:

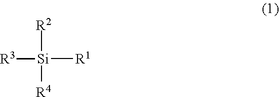

wherein,
R¹ is C₁-C₂₀ alkyl,
R² to R⁴ are each independently C₁-C₄ alkoxy.

The Si/Al molar ratio refers to the molar ratio of silicon (Si) elements within the hollow aluminosilicate particles to aluminum (Al) elements used for modification.

The Si/Al molar ratio is 7 to 15 as described above, preferably 7 to 12, and more preferably 8 to 12. If the Si/Al molar ratio falls below the above range, the aluminum content increases. This may prevent the formation of a complete hollow structure due to micro-pores generated on the shell surface. Consequently, the strength of the hollow particles decreases, making it impossible to produce high-density hollow particles. Furthermore, if the Si/Al molar ratio is below the above range, unreleased aluminum may remain in the shell, potentially increasing the refractive index and causing particle aggregation. On the other hand, if the Si/Al molar ratio exceeds the above range, when forming micro-pores in the shell, not only the aluminum on the shell surfaces but also the core particles may not be completely removed, leading to an increase in the refractive index. Furthermore, it may be difficult to maintain the hollow shape during the hydrothermal reaction.

In one embodiment of the present invention, the cured film formed from the resin composition for an anti-reflective film may have a refractive index of 1.10 to 1.35 at 550 nm, preferably 1.10 or higher and less than 1.25.

By controlling the refractive index of the cured film formed from the resin composition for an anti-reflective film within the above range at 550 nm, it can be positioned on top of a high-refractive-index layer exhibiting a refractive index of 1.60 or higher to eliminate noise such as flare or ghosting, thereby improving the light collecting efficiency of the solid-state imaging device.

### Hollow Aluminosilicate Particles (A)

In one embodiment of the present invention, the hollow aluminosilicate particles (A) serve to enhance anti-reflective properties by lowering the refractive index while maintaining coating strength.

The hollow aluminosilicate particles (A) are Al-modified silica particles, the Si/Al molar ratio of which is 7 to 15, preferably 7 to 12, and more preferably 8 to 12.

As the hollow aluminosilicate particles (A) are modified with Al, they result in low aggregation and excellent dispersibility, and they can achieve high density through a hydrothermal reaction.

The hollow aluminosilicate particles may be prepared by reacting a silane compound and an aluminum (Al) precursor with a template core composed of organic polymer micelles or reverse micelles to form a core-shell particle with an aluminosilicate shell, and then reacting the core-shell particle with a basic aqueous solution or an acidic aqueous solution to form micro-pores in the shell while simultaneously removing the core. If necessary, the hollow aluminosilicate particles can be subjected to an additional hydrothermal reaction to increase their density.

The organic polymer forming the micelle or inverse micelle is an amphiphilic polymer exhibiting both hydrophobic and hydrophilic properties, such as polyoxyethylene tallowamine, polyoxyethylene oleylamine, polyoxyethylene stearylamine, polyoxyethylene laurylamine, polyoxyethylene sorbitan ester, polyoxyethylene octyl ether, etc. These organic polymers may be used alone or in combination of two or more.

The organic polymers form micelles or inverse micelles within the solvent. The type of solvent is not particularly restricted and can be selected based on the characteristics of the organic polymer. Specifically, the solvent may be an alcohol, glycol ester, ketone, or a mixed solvent of these. The alcohols may include methanol, ethanol, isopropanol, etc.; the glycol esters may include methyl cellosolve, ethyl cellosolve, etc.; and the ketones may include methyl ethyl ketone, methyl isobutyl ketone, etc.

The silane compound can readily bond with an organic polymer forming the template core. This coupling can be performed by the Stober method (Werner, 1968). When manufacturing the shell by the sol-gel process using the Stober method, a stable shell can be produced through hydrolysis and condensation polymerization synthesis using an acidic or basic solution contained in a solvent.

The silane compounds may include, without limitation, alkoxysilanes, chlorosilanes, and bromosilanes. For example, tetramethoxysilane, tetraethoxysilane, tetraisopropoxysilane, phenyltrimethoxysilane, diphenyldimethoxysilane, vinyltrimethoxysilane, vinyltriethoxysilane, γ-glycidoxypropyltrimethoxysilane, γ-(meta)acryloxypropyltrimethoxysilane, γ-aminopropyltrimethoxysilane, γ-mercaptopropyltrimethoxysilane, trimethylchlorosilane, trimethylbromosilane, etc. can be used as the silane compound. These silane compounds may be used alone or in combination of two or more.

The type of aluminum precursor is not particularly limited and may include, for example, organic salts or alkoxides of aluminum.

The silane compound and aluminum precursor combine with the core material to form an aluminosilicate shell, thereby producing the core-shell particle. The produced core-shell particle can be reacted with a basic aqueous solution or an acidic aqueous solution to form micro-pores in the shell. These micro-pores facilitate the entry and exit of dissolved organic polymers. Consequently, the organic polymer inside the shell can be easily removed through a simple washing step.

The alkaline aqueous solution may be sodium hydroxide, ammonium hydroxide, potassium hydroxide, hydroxyphosphate salt, or a mixture thereof. The acidic aqueous solution may be hydrochloric acid, nitric acid, sulfuric acid, acetic acid, or a mixture thereof.

The solvent for washing may be distilled water, alcohol, glycol, glycol ester, or a mixture thereof. The alcohols may include methanol, ethanol, isopropanol, etc.; the glycols may include ethylene glycol, propylene glycol, etc.; and the glycol esters may include ethyl cellosolve, methyl cellosolve, etc.

The hydrothermal reaction may be performed at a temperature of 160 to 250° C.

In one embodiment of the present invention, the average particle diameter of the hollow aluminosilicate particles may be 30 to 150 nm, preferably 40 to 120 nm, and more preferably 50 to 90 nm. If the average particle diameter of the hollow aluminosilicate particles is within the above range, it is easy to control so as to satisfy Equation 1 described below, and the refractive index of the cured film can be more effectively controlled. If the average particle diameter of the hollow aluminosilicate particles is less than the above range, the volume of air within the hollow aluminosilicate particles decreases, making it difficult to lower the refractive index. Furthermore, the thin shell thickness may cause them to break easily, making it difficult to maintain the hollow shape. If the average particle diameter of the hollow aluminosilicate particles exceeds the above range, the flatness of the coating film deteriorates, and a difference in refractive index may occur even within the coating film.

The hollow aluminosilicate particles have a surface modified with a compound of the following formula (1) or a non-reactive resin.

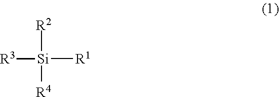

wherein,
R¹ is C₁-C₂₀ alkyl,
R² to R⁴ are each independently C₁-C₄ alkoxy.

The term “C₁-C₂₀ alkyl” as used herein means a straight-chain or branched hydrocarbon having 1 to 20 carbon atoms, and examples includes, but are not limited to, methyl, ethyl, n-propyl, i-propyl, n-butyl, i-butyl, t-butyl, pentyl, hexyl, 2-ethylhexyl, heptyl, 2-ethylheptyl, octyl, nonyl, decyl, undecyl, dodecyl, tridecyl, tetradecyl, pentadecyl, hexadecyl, heptadecyl, stearyl, nonadecyl, eicosanyl, and the like.

The term “C₁-C₄ alkoxy” as used herein means a straight-chain or branched alkoxy having 1 to 4 carbon atoms, and examples includes, but are not limited to, methoxy, ethoxy, n-propanoxy, and the like.

The compound of the above formula (1) prevents the aggregation of silicate particles due to its non-reactive alkyl group.

If the compound used for the surface modification is a reactive compound, aggregation of the hollow aluminosilicate particles may occur, impairing dispersion stability. During film formation, the aggregated particles may appear as foreign matter, resulting in poor film flatness. Furthermore, permeability at high temperatures and high humidity, as well as permeability by developers and strippers, may deteriorate.

In one embodiment of the present invention, R¹ may be preferably C₁-C₁₅ alkyl, more preferably C₁-C₁₀ alkyl, and even more preferably C₂-C₁₀ alkyl. A longer chain length of R¹ can prevent aggregation of hollow aluminosilicate particles due to steric hindrance and improve dispersibility. However, if the chain length of R¹ becomes excessively long, compatibility with polymeric materials or organic solvents in the composition may deteriorate, leading to particle precipitation or gelation. This not only results in poor storage stability but may also cause poor moisture permeability at high temperatures and humidity, as well as poor moisture permeability for developers and strippers. When the chain length of R1 is within the above preferred range, dispersion is excellent, particle aggregation during film formation is suppressed, and the film exhibits excellent flatness.

The non-reactive resin may include a repeating unit of the following formula (2).

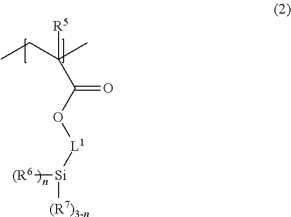

wherein,
R⁵ is hydrogen or methyl,
L¹ is absent, or C₁-C₁₀ alkylene or C₁-C₁₀ oxyalkylene,
R⁶ is hydroxy, C₁-C₄ alkoxy, or halogen,
R⁷ is hydrogen or C₁-C₂₀ alkyl, and
n is an integer from 1 to 3.

The term “C₁-C₁₀ alkylene” as used herein means a straight-chain or branched divalent hydrocarbon having 1 to 10 carbon atoms, and examples includes, but are not limited to, methylene, ethylene, n-propylene, isopropylene, n-butylene, isobutylene, n-pentylene, n-hexylene, n-heptylene, n-octylene, n-nonylene, and the like.

The term “C₁-C₁₀ oxyalkylene” as used herein means a straight-chain or branched divalent hydrocarbon having 1 to 10 carbon atoms, one or more of which are substituted with oxygen, and examples includes, but are not limited to, oxymethylene, oxethylene, oxypropylene, oxybutylene, oxypentylene, oxyhexylene, and the like.

The non-reactive resin may further include a repeating unit of the following formula (3).

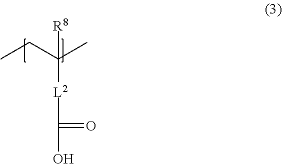

wherein,
R⁸ is hydrogen or methyl, and
L² is absent or C₁-C₁₈ alkylene.

The term “C₁-C₁₈ alkylene” as used herein means a straight-chain or branched divalent hydrocarbon having 1 to 18 carbon atoms, and examples includes, but are not limited to, methylene, ethylene, n-propylene, isopropylene, n-butylene, isobutylene, n-pentylene, n-hexylene, n-heptylene, n-octylene, n-nonylene, and the like.

Preferably, L² may be absent or may be C₁-C₆ alkylene.

In one embodiment of the present invention, the repeating unit of the above formula (2) may be included in an amount of 30 to 99 mol %, preferably 50 to 95 mol %, and more preferably 60 to 90 mol %, based on 100 mol % of the total repeating units constituting the non-reactive resin.

When the repeating unit of the above formula (2) is included within the above mol % range, it exhibits high reactivity with the silanol groups (Si—OH) on the silica surface, thereby enhancing the efficiency of surface modification.

In one embodiment of the present invention, the repeating unit of the above formula (3) may be included in an amount of 1 to 70 mol %, preferably 5 to 50 mol %, and more preferably 10 to 40 mol %, based on 100 mol % of the total repeating units constituting the non-reactive resin. When the repeating unit of the above formula (3) is included within the above mol % range, it is desirable, for example, to adjust the pH to facilitate the hydrolysis of the alkoxy groups.

The non-reactive resin may further include other repeating units in addition to the repeating units of the above formulae (2) to (3).

The non-reactive resin may be a block copolymer in which the repeating units of the above formulae (2) to (3) are each regularly repeated, or a random copolymer in which they are randomly repeated.

The method for preparing the non-reactive resin is not particularly limited and may employ methods known in the art.

The non-reactive resin may have a polystyrene equivalent weight average molecular weight (hereinafter simply referred to as “weight average molecular weight”) of 3,000 to 8,000, as measured by gel permeation chromatography (GPC; using tetrahydrofuran as the eluent). When the weight average molecular weight of the non-reactive resin is within the above range, the hydrophobicity of the modified surface is excellent, which is preferable.

The surface modification of the hollow aluminosilicate particles can be performed by hydrolyzing the compound of the above formula (1) or the non-reactive resin to form silanol (—Si—OH) groups, and then reacting them with the hollow aluminosilicate particles.

The hollow aluminosilicate particles may be included in an amount of 10 to 99 wt %, preferably 40 to 95 wt %, based on 100 wt % of the total solid content of the resin composition for an anti-reflective film. When further including the amorphous silica particles described below, the hollow aluminosilicate particles may be included in an amount of 20 to 80 wt %, preferably 35 to 75 wt %, based on 100 wt % of the total solid content of the resin composition for an anti-reflective film. If the hollow aluminosilicate particles are included in an amount below the above content range, they cannot exhibit a low refractive index effect and thus cannot function as an anti-reflective film. If included in an amount exceeding the above content range, film formation becomes difficult.

### Binder Resin (C)

In one embodiment of the present invention, the binder resin (C) possesses reactivity under the action of heat and performs the function of a tackifying resin.

Furthermore, the binder resin (C) possesses excellent moisture resistance and chemical resistance under high-temperature, high-humidity environments, thereby preventing a decrease in anti-reflective efficiency caused by an increase in refractive index.

In one embodiment of the present invention, the binder resin includes a polysiloxane compound.

The polysiloxane compound may include a hydrolysis condensate of a silane compound of the following formula (4):

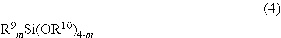

wherein,
R⁹ is C₁-C₂₀ alkyl, vinyl, aryl, or aralkyl,
R¹⁰ is C₁-C₄ alkyl, and
m is an integer from 0 to 3.

The term “aryl” as used herein encompasses all of an aromatic group, a heteroaromatic group, and their partially reduced derivatives. The aromatic group is a simple or fused ring having 5 to 15 atoms, and the heteroaromatic group refers to an aromatic group containing one or more oxygen, sulfur, or nitrogen atoms. Examples of representative aryl groups include phenyl, naphthyl, pyridinyl, pyrimidinyl, pyrrolyl, furanyl, thiophenyl, indolyl, quinolinyl, imidazolyl, oxazolyl, thiazolyl, and tetrahydronaphthyl, but are not limited to these.

The term “aralkyl” as used herein means a complex group formed by substituting an aryl group (aromatic hydrocarbon group) for a carbon of an alkyl group, and examples include, but are not limited to, benzyl, phenethyl, and the like.

The term “C₁-C₄ alkyl” as used herein means a straight-chain or branched monovalent hydrocarbon having 1 to 4 carbon atoms, and examples include, but are not limited to, methyl, ethyl, n-propyl, i-propyl, n-butyl, i-butyl, t-butyl, and the like.

In one embodiment of the present invention, the polysiloxane compound may include a hydrolyzed condensation product of a mixture of silane compounds of the following formulae (4-1) to (4-4), in terms of improving crosslinking properties and thereby increasing the degree of cure and improving the reliability of the coating film.

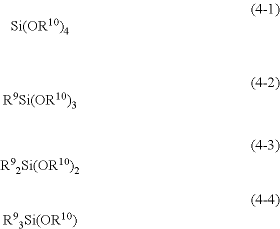

wherein,
R⁹ is C₁-C₂₀ alkyl, vinyl, aryl, or aralkyl, and
R¹⁰ is C₁-C₄ alkyl.

The silane compounds of the above formula (4-1) may include tetramethoxysilane, tetraethoxysilane, tetra-n-propoxysilane, tetra-i-propoxysilane, tetra-n-butoxysilane, and the like.

The silane compounds of the above formula (4-2) may include methyl trimethoxysilane, methyl triethoxysilane, methyl tripropoxysilane, methyl tributoxysilane, ethyl trimethoxysilane, ethyl triethoxysilane, phenyl trimethoxysilane, phenyl triethoxysilane, benzyl trimethoxysilane, benzyl triethoxysilane, vinyl trimethoxysilane, vinyl triethoxysilane, and the like.

The silane compounds of the above formula (4-3) may include dimethyldimethoxysilane, dimethyldiethoxysilane, diethyldimethoxysilane, diethyldiethoxysilane, phenylmethyl dimethoxysilane, phenylmethyl diethoxysilane, diphenyl dimethoxysilane, diphenyl diethoxysilane, benzylmethyl dimethoxysilane, benzylmethyl diethoxysilane, and the like.

The silane compounds of the above formula (4-4) may include trimethylmethoxysilane, trimethylethoxysilane, triethylmethoxysilane, triethylethoxysilane, triphenylmethoxysilane, triphenylethoxysilane, benzyldimethylmethoxysilane, benzyldimethylethoxysilane, and the like.

The mixing ratio of the silane compounds of the above formulae (4-1) to (4-4) may be 1: 1.5 to 2.5:2.5 to 3.5:3.5 to 4.5 on a molar basis, preferably 1:1.7 to 2.3:2.7 to 3.3:3.7 to 4.3, and more preferably 1:1.9 to 2.1:2.9 to 3.1:3.9 to 4.1, in terms of controlling the degree of crosslinking of polysiloxane.

The polysiloxane compound may be prepared by a hydrolytic sol-gel reaction of the silane compound of the above formula (4).

Specifically, the alkoxy group of the silane compound of the above formula (4), which is the starting material, is hydrolyzed with water to form a hydroxyl group, and a siloxane bond is formed through a condensation reaction with the alkoxy group or hydroxyl group of another silane compound of the above formula (4), thereby forming a polysiloxane.

A catalyst may be added to promote the above hydrolytic sol-gel reaction. Suitable catalysts include acid catalysts such as acetic acid, phosphoric acid, sulfuric acid, hydrochloric acid, nitric acid, chlorosulfonic acid, para-toluic acid, trichloroacetic acid, polyphosphoric acid, pyrophosphoric acid, iodic acid, tartaric acid, and perchloric acid; base catalysts such as ammonia, sodium hydroxide, n-butylamine, di-n-butylamine, tri-n-butylamine, imidazole, ammonium perchlorate, potassium hydroxide, and barium hydroxide; and ion exchange resins such as Amberite IPA-400(Cl). The amount of the catalyst to be used is not particularly limited, and 0.0001 to 10 parts by weight can be added per 100 parts by weight of the silane compound.

The above hydrolytic sol-gel reaction can be carried out by stirring at room temperature for 6 to 144 hours, or it can be carried out at 60 to 80° C. for 4 to 36 hours to accelerate the reaction rate and ensure complete condensation reaction.

The binder resin may be included in an amount of 1 to 90 wt %, preferably 5 to 60 wt %, based on 100 wt % of the total solid content of the resin composition for an anti-reflective film. When further including the amorphous silica particles described below, the binder resin may be included in an amount of 1 to 50 wt %, preferably 5 to 30 wt %, based on 100 wt % of the total solid content of the resin composition for an anti-reflective film. When the amount of the binder resin satisfies the above range, it maintains stability even at high temperatures and exhibits high resistance to many chemicals, thereby improving chemical resistance, corrosion resistance, etc. If the amount of the binder resin is below the above range, insufficient curing may result in poor adhesion to the substrate and poor chemical resistance. If the amount exceeds the above range, the particle content may relatively decrease, potentially increasing the refractive index.

### Solvent (D)

The solvent (D) is not particularly limited and may be any organic solvent used in the relevant technical field.

Specific examples of the above solvent (D) include ethylene glycol monoalkyl ethers such as ethylene glycol monomethyl ether, ethylene glycol monoethyl ether, ethylene glycol monopropyl ether, and ethylene glycol monobutyl ether; diethylene glycol dialkyl ethers such as diethylene glycol dimethyl ether, diethylene glycol diethyl ether, diethylene glycol ethyl methyl ether, diethylene glycol dipropyl ether, and diethylene glycol dibutyl ether; ethylene glycol alkyl ether acetates such as methyl cellosolve acetate, ethyl cellosolve acetate, ethylene glycol monobutyl ether acetate, and ethylene glycol monoethyl ether acetate; alkylene glycol alkyl ether acetates such as propylene glycol monomethyl ether acetate, propylene glycol monoethyl ether acetate, propylene glycol monopropyl ether acetate, methoxybutyl acetate, and methoxypentyl acetate; propylene glycol monoalkyl ethers such as propylene glycol monomethyl ether, propylene glycol monoethyl ether, propylene glycol monopropyl ether, and propylene glycol monobutyl ether; propylene glycol dialkyl ethers such as propylene glycol dimethyl ether, propylene glycol diethyl ether, propylene glycol ethyl methyl ether, propylene glycol dipropyl ether, propylene glycol propyl methyl ether, and propylene glycol ethyl propyl ether; propylene glycol alkyl ether propionates such as propylene glycol methyl ether propionate, propylene glycol ethyl ether propionate, propylene glycol propyl ether propionate, and propylene glycol butyl ether propionate; butyldiol monoalkyl ethers such as methoxybutyl alcohol, ethoxybutyl alcohol, propoxybutyl alcohol, and butoxybutyl alcohol; butanediol monoalkyl ether acetates such as methoxybutyl acetate, ethoxybutyl acetate, propoxybutyl acetate, and butoxybutyl acetate; butanediol monoalkyl ether propionates such as methoxybutyl propionate, ethoxybutyl propionate, propoxybutyl propionate, and butoxybutyl propionate; dipropylene glycol dialkyl ethers such as dipropylene glycol dimethyl ether, dipropylene glycol diethyl ether, and dipropylene glycol methyl ethyl ether; aromatic hydrocarbons such as benzene, toluene, xylene, and mesitylene; ketones such as methyl ethyl ketone, acetone, methyl amyl ketone, methyl isobutyl ketone, and cyclohexanone; alcohols such as ethanol, propanol, butanol, hexanol, cyclohexanol, ethylene glycol, and glycerin; esters such as methyl acetate, ethyl acetate, propyl acetate, butyl acetate, ethyl 2-hydroxypropionate, methyl 2-hydroxy-2-methylpropionate, ethyl 2-hydroxy-2-methylpropionate, methyl hydroxyacetate, ethyl hydroxyacetate, butyl hydroxyacetate, methyl lactate, ethyl lactate, propyl lactate, butyl lactate, methyl 3-hydroxypropionate, ethyl 3-hydroxypropionate, propyl 3-hydroxypropionate, butyl 3-hydroxypropionate, methyl 2-hydroxy-3-methylbutanoate, methyl methoxyacetate, ethyl methoxyacetate, propyl methoxyacetate, butyl methoxyacetate, methyl ethoxyacetate, ethyl ethoxyacetate, propyl ethoxyacetate, butyl ethoxyacetate, methyl propoxyacetate, ethyl propoxyacetate, propyl propoxyacetate, butyl propoxyacetate, methyl butoxyacetate, ethyl butoxyacetate, propyl butoxyacetate, butyl butoxyacetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, and butyl 3-butoxypropionate; cyclic ethers such as tetrahydrofuran and pyran; cyclic esters such as γ-butyrolactone, etc. The solvents (D) exemplified here can be used alone or in combination of two or more.

Considering the applicability and drying properties, the solvent (D) may preferably be diethylene glycol dialkyl ethers, alkylene glycol alkyl ether acetates, ketones, butanediol monoalkyl ether acetates, butanediol monoalkyl ethers, esters such as ethyl 3-ethoxypropionate and methyl 3-methoxypropionate, and more preferably diethylene glycol ethyl methyl ether, propylene glycol monomethyl ether acetate, propylene glycol monoethyl ether acetate, cyclohexanone, methoxybutyl acetate, methoxybutanol, ethyl 3-ethoxypropionate and methyl 3-methoxypropionate.

The solvent may be included in an amount of 90 to 97 wt % based on 100 wt % of the total resin composition for an anti-reflective film. It is desirable that the solvent content is within the above range because it improves the coating properties when applied using coating devices such as spin coaters, slit-and-spin coaters, slit coaters (sometimes called die coaters or curtain flow coaters), and inkjets.

The resin composition for an anti-reflective film according to one embodiment of the present invention may further include amorphous silica particles (B).

### Amorphous Silica Particles (B)

In one embodiment of the present invention, the amorphous silica particles (B) serve to suppress crack generation while maintaining film strength and to improve the flatness of the film.

The amorphous silica particles (B) do not have a hollow space inside their structure and are silica particles lacking regularity in particle shape.

Commercially available amorphous silica particles (B) can be obtained and used.

For example, the amorphous silica particles (B) include MT-10, DM-10, DM-30, DM-20S, DM-30S, KS-20SC, HG-09, HM-20L, HM-30S, ZD-30ST, PM-09, PM-20, X-20, X-30 (manufactured by Tokuyama Corporation), but are not limited thereto.

In one embodiment of the present invention, the average particle diameter of the amorphous silica particles may be 7 to 25 nm, preferably 7 to 22 nm, and more preferably 12 to 22 nm. When the average particle diameter of the amorphous silica particles falls within the above range, it is easier to control them to satisfy Equation 1 described below, and the refractive index of the cured film can be more effectively controlled. If the average particle diameter of the amorphous silica particles is below the above range, gelation of the particles during storage may not be suppressed. If it exceeds the above range, the refractive index increases, the surface roughness of the coating increases, and haze may occur.

The amorphous silica particles may be included in an amount of 70 wt % or less, for example 10 to 70 wt %, preferably 20 to 50 wt %, based on 100 wt % of the total solid content of the resin composition for an anti-reflective film. When the amorphous silica particles are included within the above content range, sufficient filling between the hollow aluminosilicate particles within the coating film can be achieved, thereby reducing the surface roughness of the coating film. If the amorphous silica particles are included in an amount exceeding 70 wt %, the content of the hollow aluminosilicate particles is relatively reduced, making it difficult to lower the refractive index.

The resin composition for an anti-reflective film according to one embodiment of the present invention may satisfy the following Equation 1:

$$1 \leq a / b \leq 15 \qquad [ Equation 1 ]$$

wherein,
a is an average particle diameter of the hollow aluminosilicate particles, and
b is an average particle diameter of the amorphous silica particles.

The a/b value is the average particle diameter ratio of hollow aluminosilicate particles relative to amorphous silica particles, and as shown in the above Equation 1, it is 1 to 15, preferably 1 to 13, and more preferably 1.8 to 12.5. If the a/b value falls below the above range, the refractive index increases due to the amorphous silica particles having a large particle diameter, and the amorphous silica particles may not sufficiently fill the spaces between the hollow aluminosilicate particles, which may result in a decrease in the flatness of the coating film. If the above range is exceeded, the flatness of the coating film may be decreased due to the hollow aluminosilicate particles having a large particle diameter.

The resin composition for an anti-reflective film according to one embodiment of the present invention may further include a leveling agent.

The leveling agent may be a commercially available surfactant, such as silicone-based, fluorine-based, ester-based, cationic, anionic, nonionic, or amphoteric surfactants. These may be used alone or in combination of two or more.

Examples of the silicone-based surfactants include commercially available products such as Dow Corning Toray Silicones' DC3PA, DC7PA, SH11PA, SH21PA, SH8400, and GE Toshiba Silicones' TSF-4440, TSF-4300, TSF-4445, TSF-4446, TSF-4460, TSF-4452, etc. Examples of the fluorine-based surfactants include commercially available products such as Megafac F-470, F-471, F-475, F-482, F-489, F-554, etc., from Dainippon Ink & Chemicals, Inc.

The leveling agent may be included in an amount of 0.0001 to 0.01 wt % based on 100 wt % of the total resin composition for an anti-reflective film. It is desirable that the content of the leveling agent is within the above range because the film-forming properties of the resin composition for an anti-reflective film are excellent, and the flatness of the coating film formed therefrom is improved.

The resin composition for an anti-reflective film according to one embodiment of the present invention may further include additives such as a curing agent, a slip improving agent, an adhesion promoter, an antioxidant, a UV absorber, an anti-coagulant, a radical generator, and a photoacid generator, as needed.

The curing agent is used to enhance deep curing and mechanical strength. Specific examples of the curing agent include epoxy compounds, polyfunctional isocyanate compounds, melamine compounds, and oxetane compounds.

Specific examples of the epoxy compound in the above curing agent include bisphenol A epoxy resins, hydrogenated bisphenol A epoxy resins, bisphenol F epoxy resins, hydrogenated bisphenol F epoxy resins, novolac epoxy resins, other aromatic epoxy resins, alicyclic epoxy resins, glycidyl ester resins, glycidyl amine resins, or brominated derivatives of these epoxy resins, aliphatic, alicyclic or aromatic epoxy compounds other than epoxy resins and brominated derivatives thereof, butadiene (co)polymer epoxides, isoprene (co)polymer epoxides, glycidyl (meth)acrylate (co)polymers, triglycidyl isocyanurate, etc.

Specific examples of the oxetane compound in the above curing agent include carbonate bisoxetane, xylene bisoxetane, adipate bisoxetane, terephthalate bisoxetane, cyclohexanedicarboxylic acid bisoxetane, etc.

The curing agent may be used in combination with a curing auxiliary compound capable of promoting the ring-opening polymerization of the epoxy group of the epoxy compound and the oxetane skeleton of the oxetane compound. Examples of the above curing auxiliary compound include polycarboxylic acids, polycarboxylic acid anhydrides, acid generators, etc.

The above polycarboxylic acid anhydrides may be commercially available as epoxy resin curing agents. Examples of the epoxy resin curing agents include trade name Adeka Hardener EH-700 (manufactured by ADEKA Corporation), trade name Rikacid HH (manufactured by New Japan Chemical Co., Ltd.), trade name MH-700 (manufactured by New Japan Chemical Co., Ltd.), etc. The curing agents can be used alone or in combination of two or more.

Examples of commercially available slip improving agent include BYK-333 (BYK-Chemie GmbH).

The adhesion promoter is preferably a silane-based compound. Specifically, examples of the adhesion promoter include vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloyloxypropyltrimethoxysilane, 3-mercaptopropyltrimethoxysilane, 3-isocyanatepropyltriethoxysilane, and the like.

Specific examples of the antioxidant include 2-tert-butyl-6-(3-tert-butyl-2-hydroxy-5-methylbenzyl)-4-methylphenyl acrylate, 2-[1-(2-hydroxy-3,5-di-tert-pentylphenyl)ethyl]-4,6-di-tert-pentylphenyl acrylate, 6-[3-(3-tert-butyl-4-hydroxy-5-methylphenyl)propoxy]-2,4,8,10-tetra-tert-butyl-dibenzo[d,f][1,3,2]dioxaphosphepin, 3,9-bis[2-{3-(3-tert-butyl-4-hydroxy-5-methylphenyl)propynyloxy}-1,1-dimethylethyl]-2,4,8,10-tetraoxaspiro[5.5]undecane, 2,2′-methylenebis(6-tert-butyl-4-methylphenol), 4,4′-butylidenebis(6-tert-butyl-3-methylphenol), 4,4′-thiobis(2-tert-butyl-5-methylphenol), 2,2′-thiobis(6-tert-butyl-4-methylphenol), dilauryl 3,3′-thiodipropionate, dimyristyl 3,3′-thiodipropionate, distearyl 3,3′-thiodipropionate, pentaerythrityltetrakis(3-laurylthiopropionate), 1,3,5-tris(3,5-di-tert-butyl-4-hydroxybenzyl)-1,3,5-triazine-2,4,6(1H,3H,5H)-trione, 3,3′,3″,5,5′,5′-hexa-tert-butyl-a,a′,a″-(mesitylene-2,4,6-triyl)tri-p-cresol, pentaerythritol tetrakis[3-(3,5-di-tert-butyl-4-hydroxyphenyl)propionate], 2,6-di-tert-butyl-4-methylphenol, and the like.

Specific examples of the ultraviolet absorber include 2-(3-tert-butyl-2-hydroxy-5-methylphenyl)-5-chlorobenzotriazole, alkoxybenzophenone, and the like.

Specific examples of the anti-coagulant include sodium polyacrylate, and the like.

Specific examples of the radical generator may include commercially available products such as OXE 01 (BASF).

Specific examples of the photoacid generator may include commercially available products such as Irgacure 290 (BASF).

One embodiment of the present invention relates to an anti-reflective film formed using the aforementioned resin composition for an anti-reflective film.

According to the present invention, the anti-reflective film can be prepared by applying the aforementioned resin composition for an anti-reflective film onto a substrate and then applying heat.

A preferred example of the preparation process involves coating the substrate with the resin composition for an anti-reflective film, followed by heating and drying to remove volatile components such as solvents, thereby obtaining a smooth film.

Coating methods may include, for example, spin coating, flexible coating, roll coating, slit and spin coating, or slit coating.

After coating, the film is heated and dried (pre-bake), or dried under reduced pressure followed by heating to volatilize volatile components such as solvents. Here, the heating temperature is typically 70 to 200° C., preferably 80 to 130° C.

Subsequently, exposure and development processes may be performed as needed.

Finally, a reheating process (post-bake) is performed to form the cured network. Here, the heating temperature is typically around 70 to 230° C. Heating methods may include hot plates, clean ovens, or infrared heaters. However, the present invention does not limit the heating method.

Using the resin composition for an anti-reflective film of the present invention, a cured film can be formed on a substrate through each of the above processes.

The cured film thus obtained can be usefully employed as an anti-reflective film for a solid-state imaging device.

The thickness of the cured film may be 50 to 700 nm.

Accordingly, one embodiment of the present invention relates to a solid-state imaging device including the aforementioned anti-reflective film.

The solid-state imaging device may include, for example, a CCD (charge coupled device) or a CMOS (complementary metal oxide semiconductor) image sensor.

The solid-state imaging device includes a support containing a semiconductor device or a photoelectric conversion device and a micro lens, and the anti-reflective film may be formed on the micro lens.

Hereinafter, the present invention will be described more specifically by means of Examples, Comparative Examples, and Experimental Examples. These Examples, Comparative Examples, and Experimental Examples are intended to illustrate the present invention only, and it is obvious to those skilled in the art that the scope of the present invention is not limited to them.

### Synthesis Example 1: Preparation of Binder Resin

In a reaction vessel equipped with a stirring device, a reflux condenser, a thermometer, and a drop funnel, first, 400 g of isopropyl alcohol was added. Then, tetraethoxysilane, phenyltriethoxysilane, dimethyldimethoxysilane, and trimethylmethoxysilane were added in a molar ratio of 1:2:3:4 to achieve a total mass of 100 g. Next, while stirring, water and nitric acid were added respectively in amounts such that the number of water molecules was 4 times the total number of molecules of the silane compounds, and the number of nitric acid molecules was 0.1 times, and the reaction was performed at 60° C. for 6 hours under a nitrogen stream. The obtained reactant was filtered, washed with isopropyl alcohol, and dried under reduced pressure under heating to obtain polysiloxane compound C-1.

### Synthesis Example 2: Preparation of Binder Resin

In a flask equipped with a stirrer, a thermometer, a reflux condensing tube, a dropping lot, and a nitrogen inlet tube, 100 parts by mass of propylene glycol monomethyl ether acetate, 94 parts by mass of propylene glycol monomethyl ether, 2 parts by mass of AIBN, 19.0 parts by mass of acrylic acid, 10 parts by mass of benzyl methacrylate, 51.0 parts by mass of styrene, and 3 parts by mass of n-dodecyl mercaptan were charged and replaced with nitrogen. Thereafter, the temperature of the reaction solution was raised to 110° C. while stirring, and the reaction was carried out for 6 hours. Subsequently, the temperature of the reaction solution was lowered to room temperature, and the flask atmosphere was replaced from nitrogen to air, after which 0.3 parts by mass of triethylamine and 20 parts by mass of glycidyl methacrylate were charged and the reaction was carried out at 110° C. for 5 hours. The solid acid value of the alkali-soluble resin synthesized in this way was 80 mgKOH/g, and the weight average molecular weight Mw measured by GPC was approximately 12,000.

### Synthesis Example 3: Preparation of Binder Resin

In a flask equipped with a stirrer, a thermometer, a reflux condensing tube, a dropping lot, and a nitrogen inlet tube, 120 parts by mass of propylene glycol monomethyl ether acetate, 80 parts by mass of propylene glycol monomethyl ether, 5 parts by mass of AIBN, 10 parts by mass of methacrylic acid, and 90 parts by mass of a mixture of 3,4-epoxytricyclo[5.2.1.0^{2.6}]decan-8-yl acrylate and 3,4-epoxytricyclo[5.2.1.0^{2.6}]decan-9-yl acrylate (content ratio is 50:50 in molar ratio) [trade name: “E-DCPA”, Daicel] were charged and replaced with nitrogen. Thereafter, the temperature of the reaction solution was raised to 85° C. while stirring, and the reaction was carried out for 6 hours. The solid acid value of the alkali-soluble resin synthesized in this way was 54 mgKOH/g, and the weight average molecular weight Mw measured by GPC was 8,100.

### Synthesis Example 4: Preparation of Non-Reactive Resin

A flask equipped with a stirrer, a thermometer, a reflux condensing tube, a dropping lot, and a nitrogen inlet tube was prepared. Thereafter, a polymerizable mixture containing 91.2 g of 3-[diethoxy(methyl)silyl]propyl methacrylate (0.35 mol, 70 mol %) and 12.9 g of methacrylic acid (0.15 mol, 30 mol %) was prepared.

Then, 4 g of t-butylperoxy-2-ethylhexanoate and 40 g of propylene glycol monomethyl ether acetate (PGMEA) were added to the polymerizable mixture and stirred and mixed to prepare a monomer solution, and a mixed solution of 6 g of n-dodecanethiol and 24 g of PGMEA was prepared as a chain transfer agent.

After this, 395 g of PGMEA was introduced into the flask, and the atmosphere inside the flask was changed from air to nitrogen. The flask temperature was raised to 70° C. with stirring. The monomer solution and chain transfer agent were each added dropwise through the dropping lot into the flask for 2 hours while maintaining the temperature at 70° C.

After 1 hour, the temperature was raised to 75° C. and maintained for 12 hours. Then, bubbling of a 5/95 (v/v) oxygen/nitrogen mixture gas was initiated through a gas inlet tube. Subsequently, 0.4 g of 2,2′-methylenebis(4-methyl-6-t-butylphenol) and 0.8 g of triethylamine were added to the flask and reacted at 70° C. for 8 hours to obtain non-reactive resin 1.

The solid acid value of the resin synthesized in this way was 92.3 mgKOH/g, and the weight average molecular weight Mw measured by GPC was approximately 4,500.

### Synthesis Example 5: Preparation of Non-Reactive Resin

Non-reactive resin 2 was obtained by the same method as in Synthesis Example 4, except that 3-methacryloxypropyl triethoxysilane was used instead of 3-diethoxymethylsilylpropyl methacrylate.

The solid acid value of the resin synthesized in this way was 97.3 mg KOH/g, and the weight average molecular weight Mw measured by GPC was approximately 5,500.

### Preparation Example 1-1: Preparation of Hollow Aluminosilicate Particles (A-1)

A core template for the hollow structure was prepared by adding 0.172 g of polyacrylic acid, 0.086 g of polystyrene sulfonic acid, and 3 mL of ammonium hydroxide to a 1 L three-neck round-bottom flask, followed by the addition of 60 mL of ethanol. While stirring the solution, 8 mL of 3% aluminum isopropoxide and 60 mL of ethanol containing tetraethoxysilane were added using a syringe pump to obtain spherical particles including cores. These particles were reacted with 5% sodium hydroxide, then washed with distilled water and alcohol and dried to prepare aluminosilicate particles with a hollow structure. 20g of the prepared particles and 80g of distilled water were added and ultrasonically dispersed for 1 hour using an ultrasonic disperser to prepare an aqueous dispersion of aluminosilicate stably dispersed in water. This dispersion was placed in a 1 L hydrothermal reactor and reacted at 180° C. for 10 hours, followed by precipitation and drying to produce hollow aluminosilicate particles with increased shell density. The solvent was replaced with propylene glycol monomethyl ether acetate to prepare an aluminosilicate propylene glycol monomethyl ether acetate dispersion having a solid content of 10 wt %. The average particle diameter was 78 nm, and the Si/Al molar ratio was 12.

### Preparation Example 1-2: Preparation of Hollow Aluminosilicate Particles (A-2)

A dispersion of hollow aluminosilicate particles was obtained in the same manner as in Preparation Example 1-1, except that 10 ml of 3% aluminum isopropoxide was used. The average particle diameter was 40 nm, and the Si/Al molar ratio was 10.

### Preparation Example 1-3: Preparation of Hollow Aluminosilicate Particles (A-3)

A dispersion of hollow aluminosilicate particles was obtained in the same manner as in Preparation Example 1-1, except that 12 ml of 3% aluminum isopropoxide was used. The average particle diameter was 150 nm, and the Si/Al molar ratio was 8.

### Preparation Example 1-4: Preparation of Hollow Aluminosilicate Particles (A-4)

A dispersion of hollow aluminosilicate particles was obtained in the same manner as in Preparation Example 1-1, except that 6 ml of 3% aluminum isopropoxide was used. The average particle diameter was 74 nm, and the Si/Al molar ratio was 16.

### Preparation Example 1-5: Preparation of Hollow Aluminosilicate Particles (A-5)

A dispersion of hollow aluminosilicate particles was obtained in the same manner as in Preparation Example 1-1, except that 20 ml of 3% aluminum isopropoxide was used. The average particle diameter was 74 nm, and the Si/Al molar ratio was 5.

### Preparation Example 2-1: Preparation of Surface-Modified Hollow Aluminosilicate Particles (F-1)

Surface-modified hollow aluminosilicate particles were prepared by applying the method described in Korean Chem. Eng. Res., Vol. 49, No. 2, April, 2011, pp. 181-186.

Specifically, hollow aluminosilicate particles (A-1) prepared in Preparation Example 1-1 were dried in a dry oven at 120° C. for more than 3 hours, then cooled to room temperature in a desiccator to remove adsorbed moisture before use. The solvent was made into 300 ml of ethanol and deionized water in a ratio of 80:20 (v/v %) at room temperature and pressure, and then the pH was adjusted to 3 to 5 using acetic acid and stirred at 300 rpm for about 30 minutes using a magnetic stirrer. 25.0 g of a compound (E-1) of formula (1), wherein R¹ is methyl and R² to R⁴ are methoxy, was added to the stirred solvent and stirred at 300 rpm for 1 hour to hydrolyze the alkoxy group bonded to the Si terminal. After the hydrolysis reaction was completed, 5.0 g of the hollow aluminosilicate particles (A-1) of Preparation Example 1-1 from which the moisture had been removed was placed in a round flask and a surface modification reaction was performed at 300 rpm for 2 hours. The solution after the reaction was centrifuged at 3,000 rpm for 30 minutes using a centrifuge (SUPRA 21K, Hanil Scientific), and the supernatant was discarded. The solution was washed several times with an ethanol/deionized water (80:20 v/v %) solution and pure ethanol, and after centrifugation, it was dried in a vacuum oven at 40° C. for 24 hours to obtain surface-modified hollow aluminosilicate particles (F-1).

### Preparation Example 2-2: Preparation of Surface-Modified Hollow Aluminosilicate Particles (F-2)

Surface-modified hollow aluminosilicate particles (F-2) were prepared in the same manner as in Preparation Example 2-1, except that a compound (E-2) of formula (1), wherein R¹ is ethyl and R² to R⁴ are methoxy, was used instead of the compound (E-1) of formula (1), wherein R¹ is methyl and R² to R⁴ are methoxy.

### Preparation Example 2-3: Preparation of Surface-Modified Hollow Aluminosilicate Particles (F-3)

Surface-modified hollow aluminosilicate particles (F-3) were prepared in the same manner as in Preparation Example 2-1, except that a compound (E-3) of formula (1), wherein R¹ is pentadecyl and R² to R⁴ are ethoxy, was used instead of the compound (E-1) of formula (1), wherein R¹ is methyl and R² to R⁴ are methoxy.

### Preparation Example 2-4: Preparation of Surface-Modified Hollow Aluminosilicate Particles (F-4)

Surface-modified hollow aluminosilicate particles (F-4) were prepared in the same manner as in Preparation Example 2-1, except that a compound (E-4) of formula (1), wherein R¹ is pentacosanyl and R² to R⁴ are ethoxy, was used instead of the compound (E-1) of formula (1), wherein R¹ is methyl and R² to R⁴ are methoxy.

### Preparation Example 2-5: Preparation of Surface-Modified Hollow Aluminosilicate Particles (F-5)

Surface-modified hollow aluminosilicate particles (F-5) were prepared in the same manner as in Preparation Example 2-1, except that 3-aminopropyl triethoxysilane (KBM-903) (E-5) was used instead of the compound (E-1) of formula (1), wherein R¹ is methyl and R² to R⁴ are methoxy.

### Preparation Example 2-6: Preparation of Surface-Modified Hollow Aluminosilicate Particles (F-6)

Surface-modified hollow aluminosilicate particles (F-6) were prepared in the same manner as in Preparation Example 2-1, except that 3-methacryloxypropyl trimethoxysilane (KBM-503) (E-6) was used instead of the compound (E-1) of formula (1), wherein R¹ is methyl and R² to R⁴ are methoxy.

### Preparation Example 2-7: Preparation of Surface-Modified Hollow Aluminosilicate Particles (F-7)

Surface-modified hollow aluminosilicate particles (F-7) were prepared in the same manner as in Preparation Example 2-1, except that 3-mercaptopropyl methyldimethoxysilane (KBM-802) (E-7) was used instead of the compound (E-1) of formula (1), wherein R¹ is methyl and R² to R⁴ are methoxy.

### Preparation Example 2-8: Preparation of Surface-Modified Hollow Aluminosilicate Particles (F-8)

Surface-modified hollow aluminosilicate particles (F-8) were prepared in the same manner as in Preparation Example 2-1, except that the hollow aluminosilicate particles (A-2) from Preparation Example 1-2 were used instead of the hollow aluminosilicate particles (A-1) from Preparation Example 1-1.

### Preparation Example 2-9: Preparation of Surface-Modified Hollow Aluminosilicate Particles (F-9)

Surface-modified hollow aluminosilicate particles (F-9) were prepared in the same manner as in Preparation Example 2-1, except that the hollow aluminosilicate particles (A-3) from Preparation Example 1-3 were used instead of the hollow aluminosilicate particles (A-1) from Preparation Example 1-1.

### Preparation Example 2-10: Preparation of Surface-Modified Hollow Aluminosilicate Particles (F-10)

Surface-modified hollow aluminosilicate particles (F-10) were prepared in the same manner as in Preparation Example 2-1, except that the hollow aluminosilicate particles (A-4) from Preparation Example 1-4 were used instead of the hollow aluminosilicate particles (A-1) from Preparation Example 1-1 and the compound (E-2) of formula (1), wherein R¹ is ethyl and R² to R⁴ are methoxy, was used instead of the compound (E-1) of formula (1), wherein R¹ is methyl and R² to R⁴ are methoxy.

### Preparation Example 2-11: Preparation of Surface-Modified Hollow Aluminosilicate Particles (F-11)

Surface-modified hollow aluminosilicate particles (F-11) were prepared in the same manner as in Preparation Example 2-1, except that the hollow aluminosilicate particles (A-5) from Preparation Example 1-5 were used instead of the hollow aluminosilicate particles (A-1) from Preparation Example 1-1 and the compound (E-2) of formula (1), wherein R¹ is ethyl and R² to R⁴ are methoxy, was used instead of the compound (E-1) of formula (1), wherein R¹ is methyl and R² to R⁴ are methoxy.

### Preparation Example 2-12: Preparation of Surface-Modified Hollow Aluminosilicate Particles (F-12)

Surface-modified hollow aluminosilicate particles (F-12) were prepared in the same manner as in Preparation Example 2-1, except that the non-reactive resin (E-8) of Synthesis Example 4 was used instead of the compound (E-1) of formula (1), wherein R¹ is methyl and R² to R⁴ are methoxy.

### Preparation Example 2-13: Preparation of Surface-Modified Hollow Aluminosilicate Particles (F-13)

Surface-modified hollow aluminosilicate particles (F-13) were prepared in the same manner as in Preparation Example 2-1, except that the non-reactive resin (E-9) of Synthesis Example 5 was used instead of the compound (E-1) of formula (1), wherein R¹ is methyl and R² to R⁴ are methoxy.

### Examples and Comparative Examples: Preparation of Resin Compositions for an Anti-reflective film

Resin compositions for an anti-reflective film were prepared by mixing the respective components according to the compositions shown in Tables 1 and 2 below (wt %).

TABLE 1

| | | Exam- | Exam- | Exam- | Exam- | Exam- | Exam- | Exam- | Exam- | Exam- | Exam- | Exam- |
|---|---|---|---|---|---|---|---|---|---|---|---|---|
| | | ple 1 | ple 2 | ple 3 | ple 4 | ple 5 | ple 6 | ple 7 | ple 8 | ple 9 | ple 10 | ple 11 |
| Surface- | F-1 | 2 | | | | | | | | | 4 | |
| modified | F-2 | | 2 | | | | | | | | | |
| hollow | F-3 | | | 2 | | | | | | | | |
| aluminosilicate | F-4 | | | | | | | | | | | |
| particles | F-5 | | | | | | | | | | | |
| (F) | F-6 | | | | | | | | | | | |
| | F-7 | | | | | | | | | | | |
| | F-8 | | | | 2 | | 2 | | | | | 4 |
| | F-9 | | | | | 2 | | 2 | | | | |
| | F-10 | | | | | | | | | | | |
| | F-11 | | | | | | | | | | | |
| | F-12 | | | | | | | | 2 | | | |
| | F-13 | | | | | | | | | 2 | | |
| Amorphous | B-1 | 2 | 2 | 2 | 2 | 2 | | | 2 | 2 | | |
| silica | B-2 | | | | | | 2 | 2 | | | | |
| particles (B) | B-3 | | | | | | | | | | | |
| Binder resin | C-1 | 0.5 | 0.5 | 0.5 | 0.5 | 0.5 | 0.5 | 0.5 | 0.5 | 0.5 | 0.5 | 0.5 |
| (C) | C-2 | | | | | | | | | | | |
| | C-3 | | | | | | | | | | | |
| Solvent (D) | D-1 | 95.5 | 95.5 | 95.5 | 95.5 | 95.5 | 95.5 | 95.5 | 95.5 | 95.5 | 95.5 | 95.5 |

TABLE 2

| | | Compar- | Compar- | Compar- | Compar- | Compar- | Compar- | Compar- | Compar- | Compar- | Compar- |
|---|---|---|---|---|---|---|---|---|---|---|---|
| | | ative | ative | ative | ative | ative | ative | ative | ative | ative | ative |
| | | Example 1 | Example 2 | Example 3 | Example 4 | Example 5 | Example 6 | Example 7 | Example 8 | Example 9 | Example 10 |
| Surface- | F-1 | | | | | | | | 2 | 2 | 2 |
| modified hollow | F-2 | | | | | | | | | | |
| aluminosilicate | F-3 | | | | | | | | | | |
| particles (F) | F-4 | 2 | | | | | | | | | |
| | F-5 | | 2 | | | | | | | | |
| | F-6 | | | 2 | | | | | | | |
| | F-7 | | | | 2 | | | | | | |
| | F-8 | | | | | | | 2 | | | |
| | F-9 | | | | | | | | | | |
| | F-10 | | | | | 2 | | | | | |
| | F-11 | | | | | | 2 | | | | |
| | F-12 | | | | | | | | | | |
| | F-13 | | | | | | | | | | |
| Amorphous | B-1 | 2 | 2 | 2 | 2 | 2 | 2 | | | 2 | 2 |
| silica particles | B-2 | | | | | | | | | | |
| (B) | B-3 | | | | | | | 2 | 2 | | |
| Binder resin (C) | C-1 | 0.5 | 0.5 | 0.5 | 0.5 | 0.5 | 0.5 | 0.5 | 0.5 | | |
| | C-2 | | | | | | | | | 0.5 | |
| | C-3 | | | | | | | | | | 0.5 |
| Solvent (D) | D-1 | 95.5 | 95.5 | 95.5 | 95.5 | 95.5 | 95.5 | 95.5 | 95.5 | 95.5 | 95.5 |

F-1 to F-13: Surface-modified hollow aluminosilicate particles from Preparation Examples 2-1 to 2-13
B-1: PM-09 (average particle diameter 22 nm, Tokuyama)
B-2: X-20 (average particle diameter 12 nm, Tokuyama)
B-3: QSG-100 (average particle diameter 110 nm, Shin-Etsu Chemical)
C-1: Polysiloxane compound synthesized in Synthesis Example 1
C-2: Acrylate resin synthesized in Synthesis Example 2
C-3: Epoxy resin synthesized in Synthesis Example 3
D-1: Propylene glycol monomethyl ether acetate

### Experimental Examples

Anti-reflective films were prepared using the resin compositions for an anti-reflective film prepared in the above Examples and Comparative Examples as follows. The properties of the anti-reflective films were evaluated by the methods described below. The results are shown in Tables 3 and 4 below.

Furthermore, the a/b value was calculated and shown in Tables 3 and 4. Here, a is an average particle diameter of the hollow aluminosilicate particles, and b is an average particle diameter of the amorphous silica particles.

### Preparation of Anti-reflective Films

The resin compositions for an anti-reflective film, prepared in the above Examples and Comparative Examples, were spin-coated onto 4-inch silicon wafers (manufactured by SK Siltron). The coated wafers were then pre-baked at 100° C. for 60 seconds using a hot plate. The pre-baked substrates were cooled to room temperature and then post-baked at 200° C. for 300 seconds in an oven. The cured film thickness was 100 nm.

### (1) Refractive Index Measurement

For the prepared cured film substrate, linear polarization was measured in the wavelength range of 200 nm to 1000 nm using an ellipsometer M-2000 (manufactured by J. A. Woollam Co.) at 25° C. and 50% RH, applying incident angles of 65, 70, and 75°. The measured linear polarization measurement data (Ellipsometry data(ψ, Δ)) was fitted to the Cauchy model of the following Equation 2 using Complete EASE software so that the MSE was 20 or less, and the refractive index at a wavelength of 550 nm was calculated. The refractive index was evaluated according to the following evaluation criteria.

$$n ( λ ) = A + \frac{B}{{λ}^{2}} + \frac{C}{{λ}^{4}} \qquad [ Equation 2 ]$$

In Equation 2, n(λ) is the refractive index at wavelength λ, λ is in the range of 300 nm to 1800 nm, and A, B, and C are Cauchy parameters.

### <Evaluation Criteria>

⊚: Refractive index 1.10 or higher but lower than 1.25
o: Refractive index 1.25 or higher but lower than 1.35
x: Refractive index exceeding 1.35

### (2) Crack Resistance

Cured film substrates were prepared in the same manner as the above preparation method, except the cured film thickness was formed to 500 nm.

The surface of the cured film substrate was observed to check for crack occurrence, and crack resistance was evaluated according to the following evaluation criteria.

### <Evaluation Criteria>

o: No cracks observed
x: Cracks observed

### (3) Film Flatness

The Ra value was measured using an atomic force microscope (AFM) Nanoscope (Bruker AXS) on the cured film substrate prepared above, and the film flatness was evaluated according to the following evaluation criteria.

### <Evaluation Criteria>

⊚: Ra value less than 6 nm
o: Ra value 6 nm or greater but less than 9 nm
x: Ra value 9 nm or greater
   (4) Moisture Permeability under High Temperature and Humidity

The refractive index of the prepared cured film substrate was measured before and after 500 hours of storage in a constant temperature and humidity chamber PR-1J (ESPEC Corp.) at 85° C./85% humidity. The refractive index change was calculated using Equation 3 below.

Moisture permeability under high temperature and humidity was evaluated according to the following evaluation criteria.

$$Refractive index change = [ ( Refractive index after storage - Refractive index before storage ) / Refractive index before storage ] \times 100 \qquad [ Equation 3 ]$$

### <Evaluation Criteria>

⊚: Less than 1%
o: 1% or more but less than 5%
x: 5% or more

### (5) Moisture Permeability for Developer and Stripper

For the cured film substrates prepared above, the refractive index was measured before and after 5-minute immersion in 2.38% tetramethylammonium hydroxide (TMAH) (developer) and methylpyrrolidone (stripper), respectively. The refractive index change was calculated using Equation 4 below. Permeability for the developer and stripper was evaluated according to the following evaluation criteria.

$$Refractive index change = [ ( Refractive index after immersion - Refractive index before immersion ) / Refractive index before immersion ] \times 100 \qquad [ Equation 4 ]$$

### <Evaluation Criteria>

⊚: Less than 1%
o: 1% or more but less than 5%
x: 5% or more

### (6) Foreign Matter Level

Contamination measurement was performed on the cured film substrates using KEYENCE (VHX-S770E). The number of foreign particles was counted and the foreign matter level was evaluated according to the following evaluation criteria.

### <Evaluation Criteria>

⊚: Less than 50 particles
o: 50 particles or more but less than 100 particles
x: 100 particles or more

TABLE 3

| | Example | Example | Example | Example | Example | Example | Example | Example | Example | Example | Example |
|---|---|---|---|---|---|---|---|---|---|---|---|
| | 1 | 2 | 3 | 4 | 5 | 6 | 7 | 8 | 9 | 10 | 11 |
| Average particle | 78 | 78 | 78 | 40 | 150 | 40 | 150 | 78 | 78 | 78 | 78 |
| diameter of | | | | | | | | | | | |
| hollow | | | | | | | | | | | |
| aluminosilicate | | | | | | | | | | | |
| particles (nm) | | | | | | | | | | | |
| Average particle | 22 | 22 | 22 | 22 | 22 | 12 | 12 | 22 | 22 | — | — |
| diameter of | | | | | | | | | | | |
| amorphous silica | | | | | | | | | | | |
| particles (nm) | | | | | | | | | | | |
| Si/Al ratio | 12 | 12 | 12 | 10 | 8 | 10 | 8 | 12 | 12 | 12 | 12 |
| a/b value | 3.5 | 3.5 | 3.5 | 1.8 | 6.8 | 3.3 | 12.5 | 3.5 | 3.5 | — | — |
| Refractive index | ⊚ | ◯ | ◯ | ◯ | ⊚ | ◯ | ⊚ | ◯ | ◯ | ⊚ | ◯ |
| Crack resistance | ◯ | ◯ | ◯ | ◯ | ◯ | ◯ | ◯ | ◯ | ◯ | ◯ | ◯ |
| Flatness | ⊚ | ⊚ | ⊚ | ⊚ | ◯ | ⊚ | ◯ | ⊚ | ⊚ | ◯ | ⊚ |
| Moisture | ⊚ | ⊚ | ◯ | ⊚ | ◯ | ⊚ | ◯ | ⊚ | ⊚ | ⊚ | ◯ |
| permeability | | | | | | | | | | | |
| under high | | | | | | | | | | | |
| temperature and | | | | | | | | | | | |
| humidity | | | | | | | | | | | |
| Moisture | ⊚ | ⊚ | ◯ | ◯ | ◯ | ◯ | ◯ | ⊚ | ◯ | ⊚ | ◯ |
| permeability for | | | | | | | | | | | |
| developer | | | | | | | | | | | |
| Moisture | ⊚ | ⊚ | ◯ | ◯ | ◯ | ◯ | ◯ | ⊚ | ◯ | ⊚ | ◯ |
| permeability for | | | | | | | | | | | |
| stripper | | | | | | | | | | | |
| Foreign matter | ⊚ | ⊚ | ⊚ | ⊚ | ◯ | ⊚ | ◯ | ⊚ | ⊚ | ⊚ | ⊚ |
| level | | | | | | | | | | | |

TABLE 4

| | Compar- | Compar- | Compar- | Compar- | Compar- | Compar- | Compar- | Compar- | Compar- | Compar- |
|---|---|---|---|---|---|---|---|---|---|---|
| | ative | ative | ative | ative | ative | ative | ative | ative | ative | ative |
| | Example 1 | Example 2 | Example 3 | Example 4 | Example 5 | Example 6 | Example 7 | Example 8 | Example 9 | Example 10 |
| Average particle | 78 | 78 | 78 | 78 | 74 | 74 | 40 | 78 | 78 | 78 |
| diameter of | | | | | | | | | | |
| hollow | | | | | | | | | | |
| aluminosilicate | | | | | | | | | | |
| particles (nm) | | | | | | | | | | |
| Average particle | 22 | 22 | 22 | 22 | 22 | 22 | 110 | 110 | 22 | 22 |
| diameter of | | | | | | | | | | |
| amorphous silica | | | | | | | | | | |
| particles (nm) | | | | | | | | | | |
| Si/Al ratio | 12 | 12 | 12 | 12 | 16 | 5 | 10 | 12 | 12 | 12 |
| a/b value | 3.5 | 3.5 | 3.5 | 3.5 | 3.4 | 3.4 | 0.4 | 0.7 | 3.5 | 3.5 |
| Refractive index | ◯ | ◯ | ◯ | ◯ | X | X | X | X | ◯ | ◯ |
| Crack resistance | ◯ | ◯ | ◯ | ◯ | X | X | X | X | X | X |
| Flatness | ◯ | ◯ | ◯ | ◯ | X | X | X | X | ◯ | ◯ |
| Moisture | X | X | X | X | X | X | ◯ | ◯ | X | X |
| permeability | | | | | | | | | | |
| under high | | | | | | | | | | |
| temperature and | | | | | | | | | | |
| humidity | | | | | | | | | | |
| Moisture | X | X | X | X | X | X | ◯ | ◯ | X | X |
| permeability for | | | | | | | | | | |
| developer | | | | | | | | | | |
| Moisture | X | X | X | X | X | X | ◯ | ◯ | X | X |
| permeability for | | | | | | | | | | |
| stripper | | | | | | | | | | |
| Foreign matter | X | X | X | X | X | X | ◯ | ◯ | X | X |
| level | | | | | | | | | | |

As shown in Tables 3 and 4 above, the resin compositions for an anti-reflective film of Examples 1 to 11, which include hollow aluminosilicate particles having a Si/Al molar ratio of 7 to 15 and surfaces modified with a compound of formula (1) or non-reactive resin, and a polysiloxane compound as a binder resin, exhibit a low refractive index while suppressing crack during film formation, exhibiting excellent film flatness, preventing particle aggregation and foreign matter generation, inhibiting moisture adsorption under high temperature and humidity conditions, and preventing moisture permeation by developers and strippers.

In contrast, the resin compositions for an anti-reflective film of Comparative Examples 1 to 10 exhibited increased refractive index, poor crack resistance and/or flatness of the film, foreign matter generation, moisture permeation under high temperature and humidity conditions, or moisture permeation by developers and strippers.

Although particular embodiments of the present invention have been shown and described, it will be understood by those skilled in the art that it is not intended to limit the present invention to the preferred embodiments, and it will be obvious to those skilled in the art that various changes and modifications may be made without departing from the spirit and scope of the invention.

The scope of the present invention, therefore, is to be defined by the appended claims and equivalents thereof.

1. A resin composition for an anti-reflective film comprising hollow aluminosilicate particles, a binder resin, and a solvent,
wherein the hollow aluminosilicate particles have a Si/Al molar ratio of 7 to 15, surfaces of which are modified with a compound of formula (1) or a non-reactive resin, and
the binder resin comprises a polysiloxane compound: 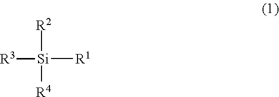
wherein,
R¹ is C₁-C₂₀ alkyl,
R² to R⁴ are each independently C₁-C₄ alkoxy.

2. The resin composition for an anti-reflective film according to claim 1, wherein an average particle diameter of the hollow aluminosilicate particles is 30 to 150 nm.

3. The resin composition for an anti-reflective film according to claim 1, wherein the non-reactive resin comprises a repeating unit of formula (2): 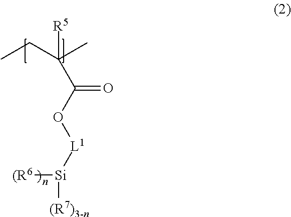
wherein,
R⁵ is hydrogen or methyl,
L¹ is absent, or C₁-C₁₀ alkylene or C₁-C₁₀ oxyalkylene,
R⁶ is hydroxy, C₁-C₄ alkoxy, or halogen,
R⁷ is hydrogen or C₁-C₂₀ alkyl, and
n is an integer from 1 to 3.

4. The resin composition for an anti-reflective film according to claim 1, wherein the polysiloxane compound comprises a hydrolysis condensation product of a silane compound of formula (4): 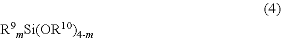
wherein,
R⁹ is C₁-C₂₀ alkyl, vinyl, aryl, or aralkyl.
R¹⁰ is C₁-C₄ alkyl, and
m is an integer from 0 to 3.

5. The resin composition for an anti-reflective film according to claim 1, further comprising amorphous silica particles.

6. The resin composition for an anti-reflective film according to claim 5, wherein the resin composition satisfies Equation 1:
$$1 \leq a / b \leq 15 \qquad [ Equation 1 ]$$
wherein,
a is an average particle diameter of the hollow aluminosilicate particles, and
b is an average particle diameter of the amorphous silica particles.

7. The resin composition for an anti-reflective film according to claim 1, wherein a cured film formed from the resin composition for an anti-reflective film has a refractive index of 1.10 to 1.35 at 550 nm.

8. An anti-reflective film formed using the resin composition for an anti-reflective film according to claim 1.

9. A solid-state imaging device having the anti-reflective film according to claim 8.
